(19) United States
(12) Patent Application Publication
(10) Pub. No.: US 2025/0107361 A1
(43) Pub. Date: Mar. 27, 2025

(54) DISPLAY SUBSTRATE AND PREPARATION METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Jiafan SHI, Beijing (CN); Liqiang CHEN, Beijing (CN); Shengxing ZHANG, Beijing (CN); Shuquan YANG, Beijing (CN); Junshan LI, Beijing (CN); Xin ZHANG, Beijing (CN); Yangjie WAN, Beijing (CN); Qian YIN, Beijing (CN)

(21) Appl. No.: 18/697,443

(22) PCT Filed: Jun. 9, 2023
(86) PCT No.: PCT/CN2023/099442

§ 371 Date: Mar. 29, 2024

(30) Foreign Application Priority Data
Jun. 13, 2022 (CN) 202210666309.9

(51) Int. Cl. H10K 59/131; H10K 59/12; H10K 77/10

(52) U.S. Cl. CPC H10K 59/131; H10K 59/1201; H10K 77/111

(57) ABSTRACT

Provided are a display substrate and a preparation method thereof, and a display device. The display substrate includes a display area and a non-display area at a periphery of the display area, and the display area includes a fanout area; the display substrate includes a data line in the display area and a fanout line in the fanout area; the fanout line (216) are electrically connected with the data line, and the fanout line and the data line are on different layers. The display device includes the display substrate. The preparation method includes: forming data line in the display area; forming fanout line on a layer that is different from the data line, where the fanout line are in the fanout area; and electrically connecting the fanout line with the data line.

### TECHNICAL FIELD

The present application relates to the field of display technology, and in particular, to a display substrate and a preparation method thereof, and a display device.

### BACKGROUND

Organic Light Emitting Diode (OLED), also known as organic electroluminescence display or organic light-emitting semiconductor, refers to a device in which organic semiconductor materials and light-emitting materials emit light through carrier injection and recombination under the driving of an electric field.

With the rapid development of the OLED display industry, a large number of new display devices are gradually entering the market. In order to obtain a higher screen-to-body ratio and provide a good visual experience to the consumer, how to further narrow the border is a trend of the display device.

### SUMMARY

In view of this, an object of the present disclosure is to provide a display substrate and a preparation method thereof, and a display device, which can reduce a size of a down border of the display substrate to a certain extent.

A first aspect of the present application provides a display substrate, including:
a display area and a non-display area at a periphery of the display area, where the display area includes a fanout area: where the display substrate includes a data line in the display area and a fanout line in the fanout area; and where the fanout line is electrically connected with the data line, and the fanout line and the data line are on different layers.

A second aspect of the present application provides a display device, including the display substrate according to the first aspect.

A third aspect of the present application provides a preparation method of a display substrate, where the display substrate includes a display area and a non-display area at a periphery of the display area, the display area includes a fanout area, and the preparation method includes:
forming a data line in the display area;
forming a fanout line in a layer that is different from the data line, where the fanout line is in the fanout area;
electrically connecting the fanout line with the data line.

As can be seen from the above, the display substrate and the preparation method thereof and the display device provided in the present application can reduce a width of the non-display area by arranging the fanout area in the display area, thereby realizing the effect of narrowing border.

### BRIEF DESCRIPTION OF DRAWINGS

In order to provide a clearer explanation of the technical solution in the application or related technologies, a brief introduction will be given below to the accompanying drawings required in the embodiments or related technical descriptions. It is obvious that the accompanying drawings in the following description are only embodiments of the application. For ordinary technical personnel in the field, other accompanying drawings can be obtained based on these drawings without creative efforts.

FIG. 1A shows a schematic diagram of an exemplary display substrate.

FIG. 1B shows a schematic diagram of a cross-sectional stacking structure of a bending area in FIG. 1A.

FIG. 1C shows a schematic diagram of a partial cross-sectional stacking structure of a display module after a bending area in FIG. 1A is bent.

FIG. 2A shows a schematic diagram of an exemplary display substrate provided in the application.

FIG. 2B shows a schematic diagram of a cross-sectional stacking structure of an exemplary display substrate provided in the application.

FIG. 2C shows a schematic diagram of a partial cross-sectional stacking structure of a display module after a bending area in FIG. 2A is bent.

FIG. 2D shows a schematic diagram of a partial cross-sectional stacking structure of another display module after a bending area in FIG. 2A is bent.

FIG. 3A shows a schematic diagram of an achievable patterned design of a metal line in a bending area.

FIG. 3B shows a schematic diagram of an achievable patterned design of a metal line in a bending area.

FIG. 3C shows a schematic diagram of an achievable patterned design of a metal line in a bending area.

FIG. 3D shows a schematic diagram of an achievable patterned design of a metal line in a bending area.

FIG. 4 is a simulation diagram of a bending morphology of the bending area provided in embodiments of the application.

FIG. 5 is a schematic diagram of the display device provided in embodiments of the application.

FIG. 6 is a schematic diagram of a method of preparing a display substrate provided in embodiments of the application.

### DETAILED DESCRIPTION

In order to make the objectives, technical solutions and advantages of the present application clearer, the present application is further described in detail below with reference to specific embodiments and with reference to the accompanying drawings.

It should be noted that, unless otherwise defined, technical terms or scientific terms used in the embodiments of the application should be of ordinary meanings understood by those skilled in the art to which the application belongs. The terms “first”, “second” and similar terms used in the embodiments of the application do not represent any order, quantity, or importance, but are merely used to distinguish different components. Terms “include” or “comprise” or the like means that an element or object appearing in front of the terms include elements or objects appearing behind the terms and their equivalents, without excluding other elements or objects. Similar terms such as “connect” or “link” are not limited to physical or mechanical connections, and may include electrical connections, whether direct or indirect. “Upper,” “lower,” “left,” “right” and the like are only used to represent relative position relationships, and when the absolute position of the described object is changed, the relative position relationship may also change accordingly.

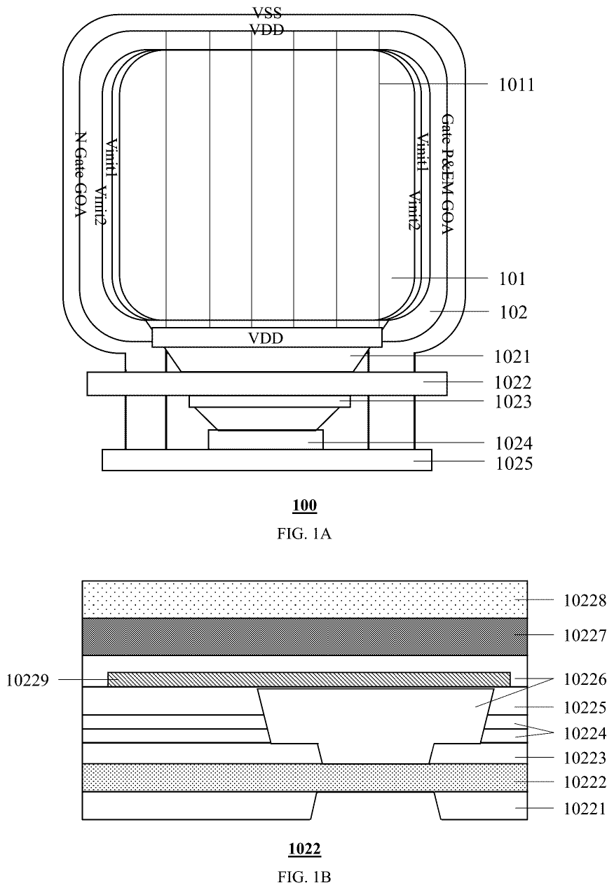

FIG. 1A shows a schematic diagram of an exemplary display substrate.

As shown in FIG. 1A, the display substrate 100 may be an OLED display substrate, and may include a display area 101 and a non-display area 102 at a periphery of the display area 101. The non-display area 102 may include a fanout area 1021, a bending area 1022, an anti-static area (may also be referred to as electrostatic discharge area, ESD area) 1023, a detection area (such as chip test area, CT area) 1024, and a binding area (such as chip on film pad area, COF PAD area) 1025. The display area 101 may also be provided with a plurality of data lines 1011 for providing data signals for pixels, and the non-display area 102 may also be provided with a first signal line VDD, a second signal line VSS, reset signal lines Vinit1/Vinit2, and gate driving circuits N_Gate GOA (Gate driver on Array)/Gate P&EM GOA (Gate driver on Array).

As shown in FIG. 1A, in the related art, a fanout area 1021 of the display substrate 100 is in the non-display area 102, and the signal may be transmitted to the bending area 1022 through metal lines. However, as the resolution of the display substrate is increased, the number of metal lines gradually increases, resulting in a continuous increase in the width required by the fanout area, which becomes a bottleneck in the reduction of the size of the down border of the display substrate.

FIG. 1B shows a schematic diagram of a cross-sectional stacking structure of a bending area in FIG. 1A.

As shown in FIG. 1B, the bending area 1022 may include a substrate 10221, a base 10222 on the substrate 10221, a buffer layer 10223 on the base 10222, a first gate insulating layer (GI) 10224 on the buffer layer 10223, and a second gate insulating layers (GI) 10224 on the first gate insulating layer (GI) 10224, a first interlayer insulating layer (such as Inter-Layer Dielectric, ILD) 10225 on the second gate insulating layer 10224, a planarization layer (PLN) 10226 on the first interlayer insulating layer 10225, a pixel defining layer (PDL) 10227 on the planarization layer 10226, and a metal coating layer (MCL) bonding layer 10228 on the pixel defining layer 10227. A metal line 10229 in the fanout area is arranged below the planarization layer 10226. As shown in FIG. 1B, the metal line 10229 is formed on the base 10222, and the material of the base 10222 includes polyimide (PI).

FIG. 1C shows a schematic diagram of a partial cross-sectional stacking structure of a display module after a bending area in FIG. 1A is bent.

As shown in FIG. 1C, a display module may include a display substrate 100, and the display substrate 100 may further include a display area (active area, AA) 101, a light emitting layer (EL) 103, and an encapsulation layer (such as thin film encapsulation, TFE) 104. Other layer-level structures may be further provided on the display substrate 100, for example, a touch structure (such as flexible multi layer on cell, FMLOC) 105, a polarizer (POL) 106, a curable optical adhesive (such as thermally optical curable adhesive, T-OCA) 107, and a cover glass (CG) 108, which are on a side of light-emitting direction; and a back protective film (BF) 109, a heat dissipation film (such as Spreader Conductive Film, SCF) 110, and a bending spacer 111 which are on a side of backlight direction. The MCL bonding layer 112 may also be formed by coating MCL adhesive at a position corresponding to the bending area.

As can be seen from FIG. 1B and FIG. 1C, in the related art, there is almost no other inorganic film layer in the bending area 1022, and only the metal line 10229 is above the base 10222, the metal line 10229 cannot be at a neutral layer position of the film layers in the bending area 1022 due to the thickness and the material property of the metal line, resulting in a great difficulty in further reducing the bending radius, and therefore, an MCL adhesive with a certain thickness (for example, 90 μm) is coated above the pixel defining layer 10227 to adjust the neutral layer position of the film layers in the bending area 1022, such that the metal line 10229 is at the neutral layer position as far as possible. The morphology of the bending area 1022 after bending is shown in FIG. 1C, a semi-circular shape is formed. However, due to the MCL bonding layer 112 is increased, the thickness of the film layers in the bending area is relatively thick, and bending of a smaller bending radius and bending of different shapes are difficult to achieve. One possible minimum bending radius is only 0.2 mm.

In view of this, embodiments of the present application provide a display substrate, which reduces a width of a border by disposing a fanout area in a display area. In some embodiments, the metal line in the bending area is between the substrate and the base, such that the metal line is substantially at the neutral layer position of the film layers, therefore the MCL bonding layer may not be coated any more, and the bending radius of the bending area may be reduced, thereby further reducing the width of the border.

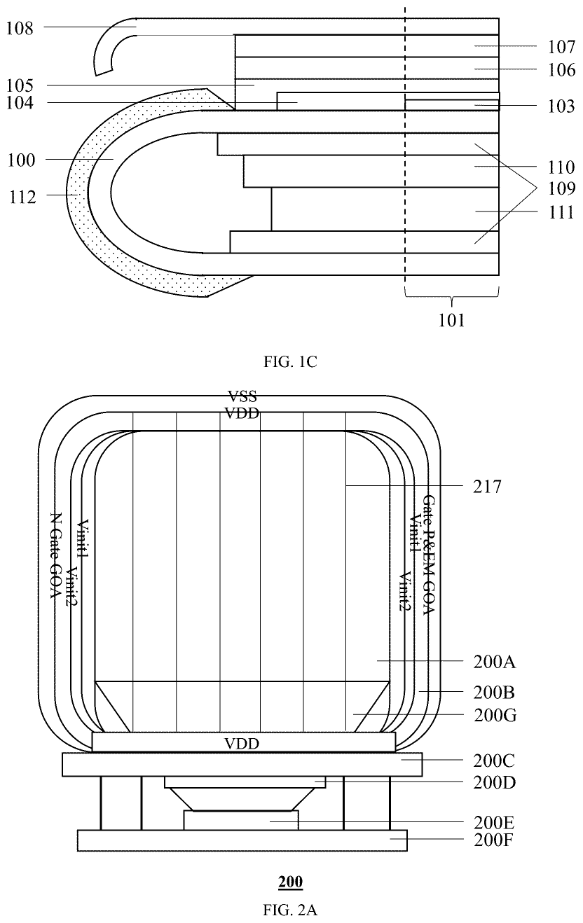

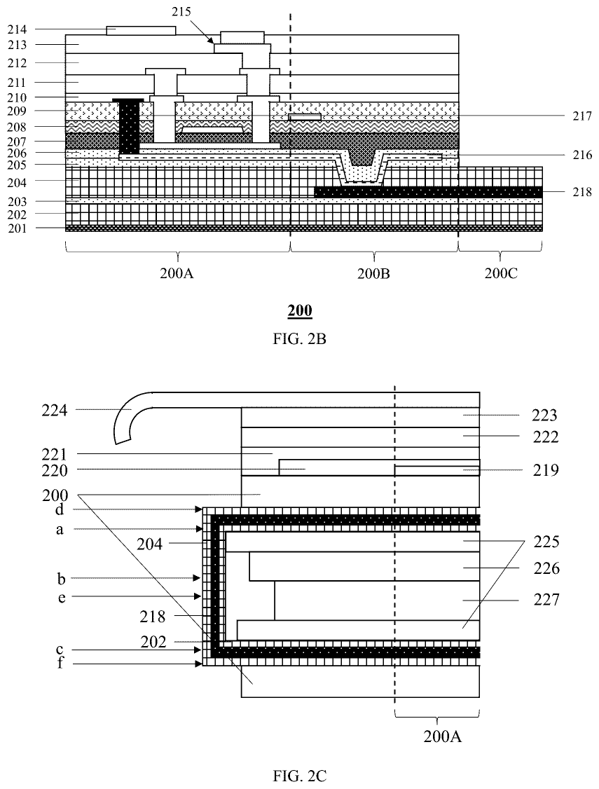

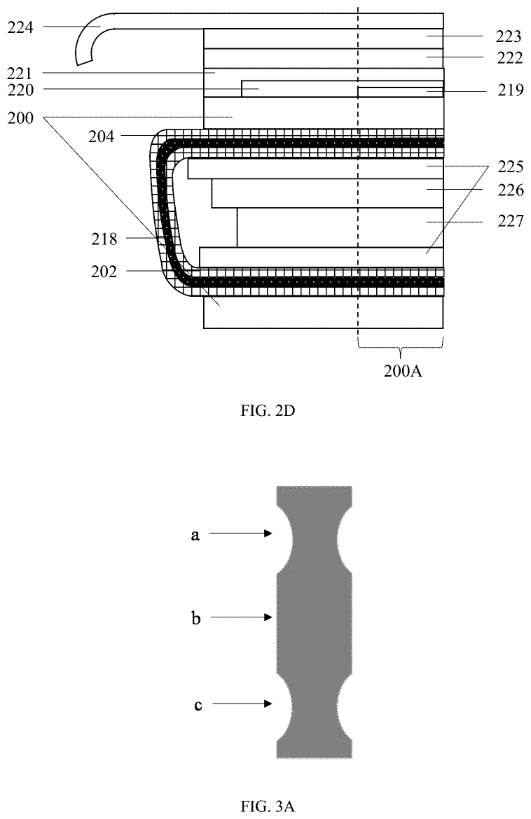

FIG. 2A illustrates a schematic diagram of an exemplary display substrate provided in the application.

As shown in FIG. 2A, the display substrate 200 may be divided into a display area 200A and a non-display area 200B at a periphery of the display area 200A. The display area 200A may be provided with a plurality of data line 217 for providing data signals for pixels, and the non-display area 200B may be provided with signal lines VDD, VSS, Vinit1/Vinit2, and may also be provided with gate driving circuits N_Gate GOA/Gate P&EM GOA. As shown in FIG. 2A, the non-display area 200B may further include a bending area 200C. In addition, in some embodiments, the display substrate 200 may further include an anti-static area 200D, a detection area 200E, and a bonding area 200F.

In order to reduce the width of the down border, in some embodiments, as shown in FIG. 2A, the fanout area 200G may be in the display area 200A, such that the fanout area 200G may no longer occupy the layout space of the non-display area 200B, thereby achieving the effect of reducing the width of the border. The fanout area 200G may a include fanout line, and the fanout line may be electrically connected to the data line 217 in a one-to-one correspondence, such that the fanout area may be used to lead the data line 217 from the fanout line to the external circuits.

In order to dispose the fanout area 200G in the display area 200A, meanwhile, the fanout line does not affect the wiring of the other lines in the display area 200A, the fanout line and the data line 217 may be disposed on different layers.

FIG. 2B shows a schematic diagram of a cross-sectional stacking structure of an exemplary display substrate provided in the application.

As shown in FIG. 2B, the display substrate 200 may be divided into a display area 200A, a non-display area 200B at a periphery of the display area 200A, and a bending area 200C in the non-display area 200B.

As shown in FIG. 2B, the display substrate 200 may be a multi-layer structure, and may further include a substrate 201 (for example, glass), a first base 202 (for example, polyimide PI), a first barrier layer 203, a second base 204 (for example, polyimide PI), a second barrier layer 205, a buffer layer 206, a first gate insulating layer 207, a second gate insulating layer 208, an interlayer insulating layer 209, a passivation layer (PVX) 210, a first planarization layer 211, a second planarization layer 212, a pixel definition layer 213, and a pad spacer (PS) 214 on the pixel definition layer 213, which are sequentially stacked. In addition, the pixel definition layer 213 for dividing pixels may further include an anode layer 215.

As an alternative embodiment, as shown in FIG. 2B, the fanout line 216 may be on the second barrier layer 205, and the fanout line 216 and the upper device structures are separated by the buffer layer 206, the first gate insulation layer 207, the second gate insulation layer 208, the interlayer insulation layer 209, and the passivation layer 210, and the like, so as to electrically isolate the fanout line 216 from affecting the layout of other device structures and lines. In some embodiments, as shown in FIG. 2B, the data line 217 can be on the interlayer insulation layer 209 which is at a different layer from the fanout line, and the fanout line 216 may be electrically connected to the data line 217 through via holes.

In this way, by disposing the fanout line 216 on a side close to the substrate and electrically connected to the data line 217 through the via holes, the fanout line 216 may be formed in the display area 200A, so as to dispose the fanout area in the display area 200A, thereby achieving a narrowing border.

As shown in FIG. 2B, in some embodiments, the display substrate 200 may further include a metal line 218 in the bending area 200C, and the metal line 218 and the fanout line 216 are electrically connected to each other in the non-display area 200B. In some embodiments, as shown in FIG. 2B, the metal line 218 and the fanout line 216 are electrically connected through via holes in the non-display area 200B, thereby avoiding the problem of water vapor eroding along the metal in the via holes to the light-emitting material layer caused by the opening of the via holes in the display area 200A, resulting in display failure.

In some embodiments, as shown in FIG. 2B, the interlayer insulating layer 209, the second gate insulating layer 208, the first gate insulating layer 207, and the buffer layer 206 may be perforated in the display area 200A to realize the connection between the data line 217 and the fanout line 216, and then the data voltage (Vdata) signal is transmitted from the data line 217 to the fanout line 216. After the fanout line 216 is narrowed in the fanout area (that is, the area occupied by the lines in the fan-out area 200G is from wide to narrow), the base hole (PI Hole(s)) is formed in the non-display area 200B after the narrow is completed, and the wiring process of the metal line 218 is performed between the first base and the second base in the non-display area 200B and the bending area 200C, and the fanout line 216 is in connection with the metal line 218 through the PI hole to realize signal transmission. The signal lines VDD. VSS. Vinit may also implement signal transmission of the data line 217→the fanout line 216→the metal line 218 in the non-display area 200B through the PI Hole(s). Therefore, the embodiment realizes the design of the fanout area in the display area 200A, as shown in FIG. 2B. The PI Hole is formed in the non-display area 200B to avoid the problem of display failure caused by water vapor erosion along the metal in the hole at the PI Hole(s) in the display area to the light-emitting material layer.

In some embodiments, as shown in FIG. 2B, the metal line 218 in the bending area 200C may be between the first base 202 and the second base 204. In this structure, the film layer structure in the bending area 200C only includes two layers of base and the metal line 218. The thicknesses of the bases on top and bottom of the metal line 218 are basically the same, for example, both 5 μm-8 μm. In this way, the metal line 218 in the bending area 200C may be in the neutral layer position, and has a relatively small strain stress during bending, such that the metal of the metal line 218 can be effectively protected, and the metal line 218 is prevented from being broken due to bending. The above-mentioned film layer structure does not need to be coated with MCL adhesive to adjust the neutral layer, the process steps and equipment are saved, and the product cost is reduced.

FIG. 2C shows a schematic diagram of a partial cross-sectional stacking structure of a display module after a bending area in FIG. 2A is bent.

As shown in FIG. 2C, the display module may include a display substrate 200, and the display substrate 200 may further include a display area 200A, a light-emitting layer 219, and an encapsulation layer 220. Other layer-level structures may be further provided on the display substrate 200, for example, a touch structure 221, a polarizer 222, a curable optical adhesive 223, a cover glass 224 which are on a side of light-emitting direction, and a back protective film 225, a heat dissipation film 226, and a bending area spacer 227 which are on a side of backlight direction.

Since the metal line 218 is between the first base and the second base, the metal line 218 may be at the neutral layer position (or referred as middle layer position) in the film layers, so as to withstand greater stress. Therefore, in some embodiments, the first base, the second base and the metal line 218 may be bent with very little bending radius or even vertically bent. As shown in FIG. 2C and FIG. 2D, partial enlarged figures are shown for the bent first base 202, the bent second base 204, and the bent metal line 218. In some embodiments, the first base 202 may further include a barrier layer to prevent water vapor from eroding the light-emitting material layer in the display substrate, resulting in display failure.

It can be seen from FIG. 2C and FIG. 2D that the thickness of the film layers including only the first base, the second base and the metal line 218 is relatively thin, for example, the thickness of each of the two bases is 5 μm-8 μm, and the thickness of the metal line 218 is about 6500 Å. Therefore, bending of a smaller bending radius or different morphologies can be performed under the conditions of material properties such as metal ductility and tensile strength of the metal line 218. Compared the topography of FIG. 2C and FIG. 2D to that of FIG. 1C, the border size of structure in FIG. 2C and FIG. 2D may reduce of 0.2-0.3 mm.

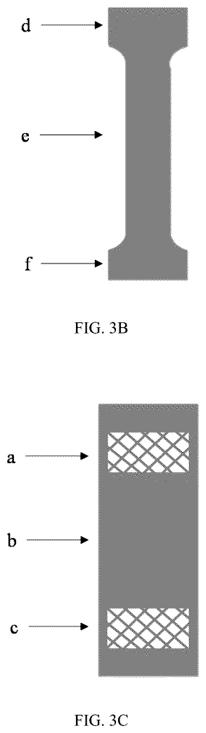

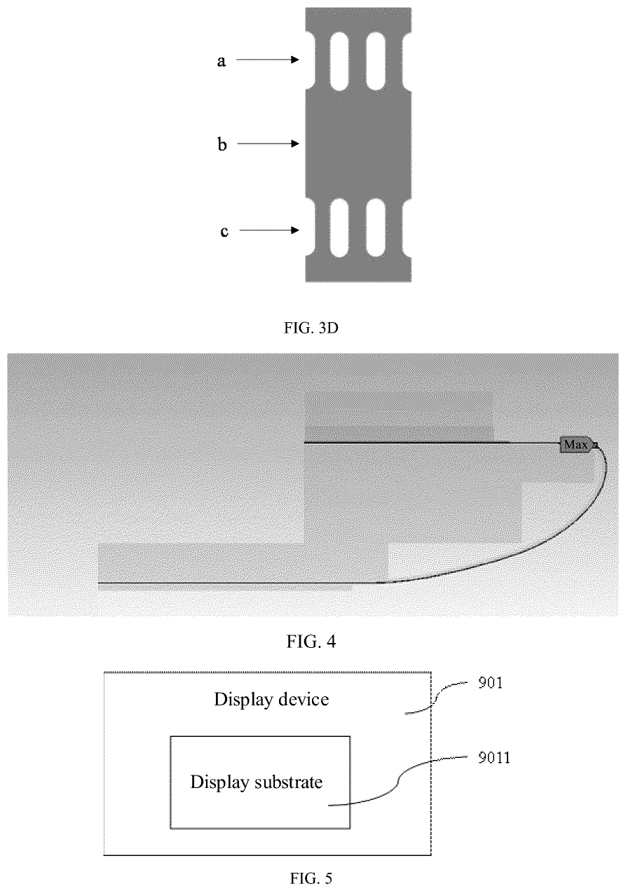

FIG. 3A to FIG. 3D respectively show schematic diagrams of achievable patterned designs of a metal line in a bending area.

In order to realize bending according to the predetermined trajectory morphology, the metal line 218 in the bending area 200C may be patterned. As shown in FIG. 2C, the first base, the second base and the metal line 218 which are in bent state may include a vertical folding area and a non-vertical folding area. The vertical folding area may further include a first portion a, a third portion c, a first end d, and a second end f, and the non-vertical folding area may include a second portion b and an intermediate portion e. To achieve vertical folding, a special-shaped area with a width of 100 μm may be designed in the vertical folding area.

In some embodiments, in order to ensure the bending area to bear the stress, the elastic modulus of the first portion a and the elastic modulus of the third portion c may be set to be less than the elastic modulus of the second portion b, such that the bending radius may be further reduced.

In some embodiments, as shown in FIG. 3A, in order to make the elastic modulus of the first portion a and the third portion c smaller than the elastic modulus of the second portion b, the wiring designs of the first portion a and the third portion c may be narrowed, such that the width of the first portion a and the width of the third portion c is smaller than the width of the second portion b.

As an optional embodiment, as shown in FIG. 3B, the width of the intermediate portion e may be designed to be smaller than the widths of the first end portion d and the second end portion f.

As an optional embodiment, as shown in FIG. 3C and FIG. 3D, in order to make the elastic modulus of the first portion a and the third portion c smaller than the elastic modulus of the second portion b respectively, the first portion a and the third portion c may be designed as a hollow structure, for example, the mesh wiring design of FIG. 3C and the hole-shaped wiring design of FIG. 3D.

As shown in FIG. 3C, as an optional embodiment, the hollow structure of the mesh design may be formed by forming an opening in the first portion a and an opening in the third portion c, and forming cross grids in the openings, where an included angle between the grid lines, for example, may be 90°.

As shown in FIG. 3D, as an optional embodiment, the hollow structure of the hole-shaped design may be a plurality of holes arranged side-by-side. In some embodiments, as shown in FIG. 3D, the holes may be elongated and has a semicircular end, such that the edge area of the metal line is formed smoother, thereby preventing the generation of static electricity and discharging. In some embodiments, as shown in FIG. 3D, openings may also be provided at edges of two sides of the metal line, such that the elastic modulus may be further reduced. The shape of the openings, for example, may be the same as the shape of a part of the holes, such that the opening and the holes may be formed by using the same opening mold, thereby saving manufacturing costs.

The pattern design in the above embodiments can significantly reduce the elastic modulus of the metal line 218, and therefore, during bending, the metal line 218 in the hollow structure area is bent first, thereby the metal line can achieve better bending according to a predetermined trajectory. In the non-vertical folding area, the metal line 218 adopts a non-pattern design, which is different from the elastic modulus of the line in the vertical folding area.

FIG. 4 is a simulation diagram of a bending morphology of the bending area provided in embodiments of the application.

As shown in FIG. 4, for the film layer structure of the metal line 218 between the first base and the second base in the bending area 200C with a bending radius of 0.05 mm, the maximum strain occurs at the starting point of bending. The strain of the metal line 218 is 9.7%, the strain of the first base 202 is 15.9%, and the strain of the second base 204 is 17.2%; where a strain threshold of the metal line is 12%, and a strain threshold of the first base 202 and a strain threshold of the second base 204 are 21%, therefore, the film layer structure in the bending area 200C and the bending topography thereof are all within the safety threshold.

The embodiment of the application further provides a display device. FIG. 5 is a schematic diagram of the display device provided in embodiments of the application.

As shown in FIG. 5, the embodiment provides a display device 901, including a display substrate 9011. The display substrate 9011 is any one embodiment or a combination of the foregoing display substrates. The display device is a product with an image display function, for example, may be: a display, a television, a billboard, a digital photo frame, a laser printer with a display function, a phone, a mobile phone, a personal digital assistant (PDA), a digital camera, a portable camcorder, a viewfinder, a navigator, a vehicle, a large area wall, a home appliance, an information query device (for example, a service query device, a monitor, and the like of a department such as an electronic government affair, a bank, a hospital, and a power supply).

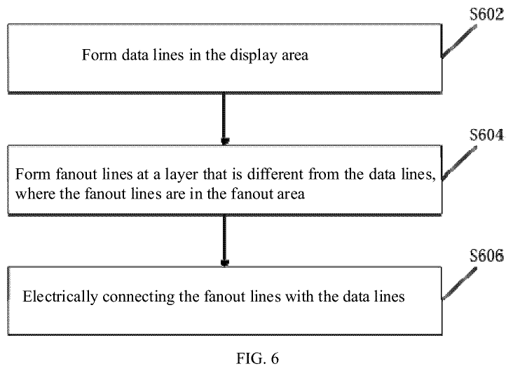

The embodiment of the application further provides a method of preparing the display substrate. FIG. 6 is a schematic diagram of a method of preparing a display substrate provided in embodiments of the application.

The embodiment provides a method of preparing a display substrate, the display substrate includes a display area and a non-display area at a periphery of the display area, and the display area includes a fanout area. As shown in FIG. 6, the method of preparing the display substrate includes:
S602: forming a data line in the display area;
S604: forming a fanout line at a layer that is different from the data line, where the fanout line is in the fanout area; and
S606: electrically connecting the fanout line with the data line.

In some embodiments, the display substrate further includes a bending area in the non-display area, and the preparation method further includes: forming a metal line in the bending area, where the metal line and the fanout line are electrically connected through a via hole in the non-display area.

In some embodiments, the display substrate further includes a first base and a second base that are stacked, and the preparation method further includes: forming the metal line between the first base and the second base.

In some embodiments, in an extending direction of the bending area, the metal line includes a first portion, a second portion and a third portion, and the preparation method further includes: forming hollow structures in the first portion and the third portion respectively: where the hollow structures are in mesh shape or hole shape.

In some embodiments, in the extending direction of the bending area, the metal line includes a first portion, a second portion and a third portion, and a width of the first portion and a width of the third portion are each smaller than a width of the second portion, respectively.

In some embodiments, the metal line includes a first end portion and a second end portion and an intermediate portion between the first end portion and the second end portion, and the preparation method further includes: forming the metal line by using patterning process such that the width of the intermediate portion is smaller than the widths of the first end portion and the second end portion respectively.

The method of the above-mentioned embodiments is used for preparing the corresponding display substrate in any one of the above-mentioned embodiments, and has the beneficial effects of the corresponding display substrate embodiments, which will not be repeated here.

It should be understood by those of ordinary skill in the art that the foregoing discussion of any embodiment is merely exemplary, and is not intended to suggest that the scope of the present application (including the claims) is limited to these examples: in the spirit of the application, the above embodiments or the technical features in different embodiments may also be combined, and the steps may be implemented in any order, and there are many other changes in different aspects of the embodiments of the application as described above, for the sake of conciseness, they are not provided in the details.

Additionally, for simplicity of illustration and discussion, and to not obscure embodiments of the present application, in the provided drawings, well-known power/ground connections with integrated circuit (IC) chips and other components may or may not be shown. Furthermore, the device may be shown in block diagram form in order to avoid obscuring the embodiments of the present application, and this also takes into account the fact that the details regarding the implementation of these block diagram devices are highly dependent on the platform in which the embodiments of the present application are to be implemented (i.e., these details should be fully within the understanding of those skilled in the art). Having set forth specific details (e.g., circuits) to describe exemplary embodiments of the present application, it will be apparent to those skilled in the art that embodiments of the present application may be implemented without these specific details or with changes to these specific details. Accordingly, these descriptions should be considered illustrative and not limiting.

Although the present application has been described in conjunction with specific embodiments of the present application, many alternatives, modifications and variations of these embodiments will be apparent to those of ordinary skill in the art from the above-mentioned description. For example, other memory architectures (e.g., dynamic RAM (DRAM)) may use the discussed embodiments.

The application is intended to cover all such alternatives, modifications and variations that fall within the broad scope of the appended claims. Therefore, any omission, modification, equivalent replacement, improvement and the like that are made within the spirit and principle of the embodiments of the application should be included within the protection scope of the application.

1. A display substrate, comprising a display area and a non-display area at a periphery of the display area, wherein the display area comprises a fanout area;
wherein the display substrate comprises a data line in the display area and a fanout line in the fanout area; and
wherein the fanout line is electrically connected with the data line, and the fanout line and the data line are on different layers.

2. The display substrate according to claim 1, wherein the display substrate further comprises a bending area in the non-display area; the display substrate further comprises a metal line in the bending area; and the metal line and the fanout line are electrically connected in the non-display area.

3. The display substrate according to claim 2, wherein the metal line and the fanout line are electrically connected through a via hole in the non-display area.

4. The display substrate according to claim 2, wherein the display substrate further comprises a first base and a second base that are arranged in stack; and the metal line is between the first base and the second base.

5. The display substrate according to claim 2, wherein the metal line comprises a first portion, a second portion and a third portion in an extending direction of the bending area; and an elastic modulus of the first portion and an elastic modulus of the third portion are each less than an elastic modulus of the second portion.

6. The display substrate according to claim 5, wherein the first portion and the third portion are provided with a hollow structure respectively.

7. The display substrate according to claim 6, wherein the hollow structure is in a mesh shape or a hole shape.

8. The display substrate according to claim 2, wherein the metal line comprises a first end portion and a second end portion and an intermediate portion between the first end portion and the second end portion; and a width of the intermediate portion is smaller than a width of the first end portion and a width of the second end portion respectively.

9. A display device, comprising a display substrate comprising a display area and a non-display area at a periphery of the display area, wherein the display area comprises a fanout area;
wherein the display substrate comprises a data line in the display area and a fanout line in the fanout area; and
wherein the fanout line is electrically connected with the data line, and the fanout line and the data line are on different layers.

10. A preparation method of a display substrate, wherein the display substrate comprises a display area and a non-display area at a periphery of the display area, the display area comprises a fanout area, and the preparation method comprises:
forming a data line in the display area;
forming a fanout line in a layer that is different from the data line, wherein the fanout line is in the fanout area; and
electrically connecting the fanout line with the data line.

11. The preparation method according to claim 10, wherein the display substrate further comprises a bending area in the non-display area, and the preparation method further comprises:
forming a metal line in the bending area;
wherein the metal line and the fanout line are electrically connected through a via hole in the non-display area.

12. The preparation method according to claim 11, wherein the display substrate further comprises a first base and a second base that are stacked, and the preparation method further comprises:
forming the metal line between the first base and the second base.

13. The preparation method according to claim 11, wherein the metal line comprises a first portion, a second portion and a third portion in an extending direction of the bending area, and the preparation method further comprises:
forming hollow structures in the first portion and the third portion respectively; wherein the hollow structures are in mesh shape or hole shape.

14. The preparation method according to claim 11, wherein the metal line comprises a first portion, a second portion and a third portion in an extending direction of the bending area,
a width of the first portion and a width of the third portion are each smaller than a width of the second portion.

15. The preparation method according to claim 11, wherein the metal line comprises a first end portion and a second end portion and an intermediate portion between the first end portion and the second end portion, and the preparation method further comprises:
forming the metal line by using patterning process, such that a width of the intermediate portion is smaller than a width of the first end portion and a width of the second end portion respectively.

16. The display substrate according to claim 5, wherein a width of the first portion and a width of the third portion are each smaller than a width of the second portion.

17. The display substrate according to claim 3, wherein the display substrate further comprises a first base and a second base that are arranged in stack; and the metal line is between the first base and the second base.

18. The display substrate according to claim 3, wherein the metal line comprises a first portion, a second portion and a third portion in an extending direction of the bending area; and an elastic modulus of the first portion and an elastic modulus of the third portion are each less than an elastic modulus of the second portion.

19. The display substrate according to claim 4, wherein the metal line comprises a first portion, a second portion and a third portion in an extending direction of the bending area; and an elastic modulus of the first portion and an elastic modulus of the third portion are each less than an elastic modulus of the second portion.

20. The display substrate according to claim 3, wherein the metal line comprises a first end portion and a second end portion and an intermediate portion between the first end portion and the second end portion; and a width of the intermediate portion is smaller than a width of the first end portion and a width of the second end portion respectively.
